(19) United States
(12) Patent Application Publication
(10) Pub. No.: US 2011/0195583 A1
(43) Pub. Date: Aug. 11, 2011

(54) WAVELENGTH CONVERTING LAYER FOR A LIGHT EMITTING DEVICE

(75) Inventor: Jeffrey D. KMETEC, Palo Alto, CA (US)

(73) Assignees: KONINKLIJKE PHILIPS ELECTRONICS N.V., Eindhoven (NL); PHILIPS LUMILEDS LIGHTING COMPANY, LLC

(21) Appl. No.: 12/704,329

(22) Filed: Feb. 11, 2010

(51) Int. Cl. H01L 21/265; G21K 1/00

(52) U.S. Cl. 438/796; 250/492.21; 257/E21.34

(57) ABSTRACT

A layer of wavelength converting material is formed by supplying energy to a particle of wavelength converting material and causing the particle to contact a surface such that the energy causes the particle to adhere to the surface. In some embodiments, the wavelength converting material is a phosphor and the surface is a surface of a semiconductor light emitting device.

### BACKGROUND

1. Field of Invention

The present invention relates to a method of forming a wavelength converting layer.

2. Description of Related Art

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions.

III-nitride LEDs are often combined with wavelength converting materials such as phosphors or dyes. An LED combined with one or more wavelength converting materials may be used to create white light or monochromatic light of other colors. All or only a portion of the light emitted by the LED may be converted by the wavelength converting material. Unconverted light may be part of the final spectrum of light, though it need not be. Examples of common devices include a blue-emitting LED combined with a yellow-emitting phosphor, a blue-emitting LED combined with green- and red-emitting phosphors, a UV-emitting LED combined with blue- and yellow-emitting phosphors, and a UV-emitting LED combined with blue-, green-, and red-emitting phosphors.

A common approach is to coat the LED with the phosphor, using an organic binder to adhere the phosphor particles to the LED. Organic binders can cause performance degradation at high temperature, and can even cause LED failure.

One alternative to powder phosphor adhered to the LED with an organic binder is a pre-formed sintered ceramic phosphor attached to the LED. One example of such a device, illustrated in FIG. 1, is described in U.S. Pat. No. 7,341,878, which is incorporated herein by reference. “Semiconductor structure 130 including a light emitting region is bonded to ceramic phosphor 52 by bonded interface 56. Contacts 18 and 20 are formed on semiconductor structure 130, which are connected to package element 132 by metal interfaces 134.” Though FIG. 1 illustrates “semiconductor structure 130 mounted on package element 132 in a flip chip configuration where both contacts 18 and 20 are formed on the same side of the semiconductor structure, in an alternative embodiment, a portion of ceramic phosphor 52 may be removed such that contact 18 is formed on the opposite side of semiconductor structure 130 as contact 20.”

Processing of pre-formed ceramic phosphors may be expensive. In addition, it can be difficult to form thin pre-formed ceramic layers.

### SUMMARY

It is an object of the invention to provide a wavelength converting layer that is adhered to a surface without an organic binder.

In embodiments of the invention, a layer of wavelength converting material is formed by supplying energy to a particle of wavelength converting material and causing the particle to contact a surface such that the energy causes the particle to adhere to the surface. In some embodiments, the wavelength converting material is a phosphor and the surface is a surface of a semiconductor light emitting device. In some embodiments, the energy is supplied by heating or accelerating the particle.

### BRIEF DESCRIPTION OF THE DRAWINGS

FIG. 1 illustrates a ceramic phosphor connected to a light emitting device.

FIG. 2 illustrates a thin film flip chip III-nitride light emitting device with a wavelength converting layer.

FIG. 3 illustrates a method of forming a wavelength converting layer.

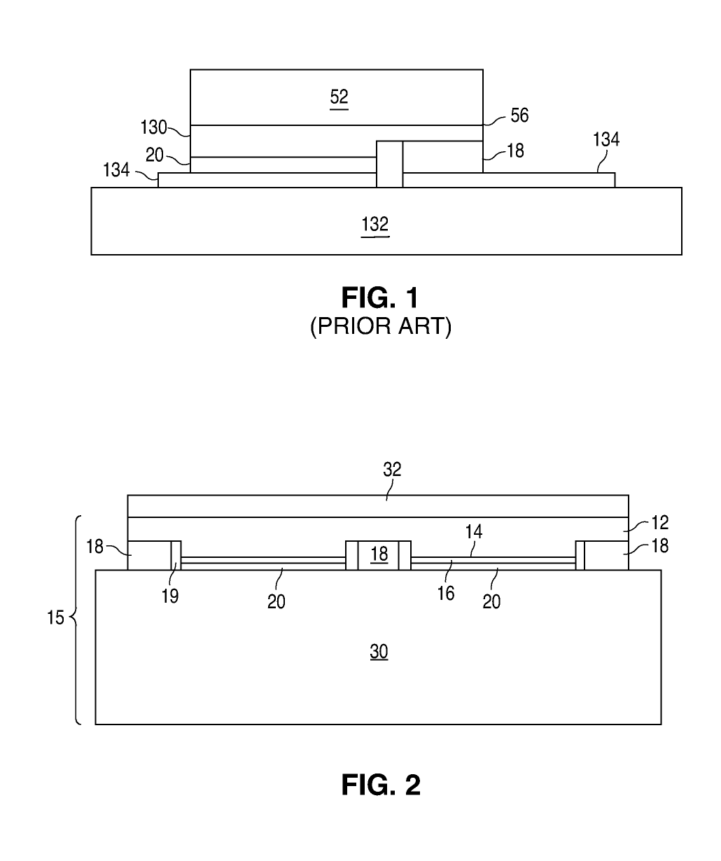

### DETAILED DESCRIPTION

In embodiments of the invention, a wavelength converting material is formed on a surface. No binder material is required to adhere the wavelength converting material to the surface. In some embodiments, the surface is a surface of a semiconductor light emitting device. Though the examples below include III-nitride light emitting diodes, embodiments of the invention may include other semiconductor devices such as laser diodes, and devices made from other materials systems such as other III-V devices, III-phosphide devices, III-arsenide devices, II-VI devices, and Si-based devices. Also, though the examples below include phosphor, other appropriate wavelength converting materials may be used.

FIG. 2 illustrates an embodiment of the invention with a phosphor formed on the surface of a III-nitride light emitting device. The device illustrated in FIG. 2 is formed by first growing a semiconductor structure on a growth substrate (not shown). The n-type region 12 is typically grown first and may include multiple layers of different compositions and dopant concentration including, for example, preparation layers such as buffer layers or nucleation layers, which may be n-type or not intentionally doped, release layers designed to facilitate later release of the substrate or thinning of the semiconductor structure after substrate removal, and n- or even p-type device layers designed for particular optical or electrical properties desirable for the light emitting region to efficiently emit light. A light emitting or active region 14 is grown over the n-type region. Examples of suitable light emitting regions include a single thick or thin light emitting layer, or a multiple quantum well light emitting region including multiple thin or thick quantum well light emitting layers separated by barrier layers. A p-type region 16 is grown over the light emitting region. Like the n-type region, the p-type region may include multiple layers of different composition, thickness, and dopant concentration, including layers that are not intentionally doped, or n-type layers.

FIG. 2 illustrates a thin film flip chip device, where the contacts are formed on the top side of the structure, the structure is flipped over and attached to a mount, then the growth substrate is removed. A semiconductor structure grown on a growth substrate may be processed into any suitable device. Other examples of device structures that may be used include vertical devices, where the n- and p-contacts are formed on opposite sides of the device, flip chip devices where the growth substrate remains a part of the device, and devices where light is extracted through transparent contacts. In a vertical device, the top contact may be formed before the phosphor layer, and phosphor deposited on the top contact may or may not be removed. Alternatively, the phosphor layer may be formed before the top contact, then patterned to remove part of the phosphor layer where the top contact is formed. Phosphor formed by the methods described below may be removed by, for example, reactive ion etching or laser ablation.

To form the device illustrated in FIG. 2, a p-contact 20 is formed on the top surface of the p-type region. P-contact 20 may include a reflective layer, such as silver. P-contact 20 may include other optional layers, such as an ohmic contact layer and a guard sheet including, for example, titanium and/or tungsten. A portion of p-contact 20, the p-type region, and the active region is removed to expose a portion of the n-type region on which one or more n-contacts 18 are formed.

Interconnects (not shown in FIG. 2) are formed on the p- and n-contacts, then the device is connected to mount 30 through the interconnects. The interconnects may be any suitable material, such as solder or other metals, and may include multiple layers of materials. In some embodiments, interconnects include at least one gold or other metal layer and the bond between the LED and the mount is formed by ultrasonic or thermosonic bonding.

After the semiconductor structure is bonded to mount 30, all or part of the growth substrate may be removed by any suitable technique for the particular growth substrate material. For example, an Al₂O₃ substrate may be removed by laser lift-off. After the growth substrate is removed, the semiconductor structure may be thinned, for example by photoelectrochemical (PEC) etching. The exposed surface of the n-type region may be textured, for example by roughening or by forming a photonic crystal.

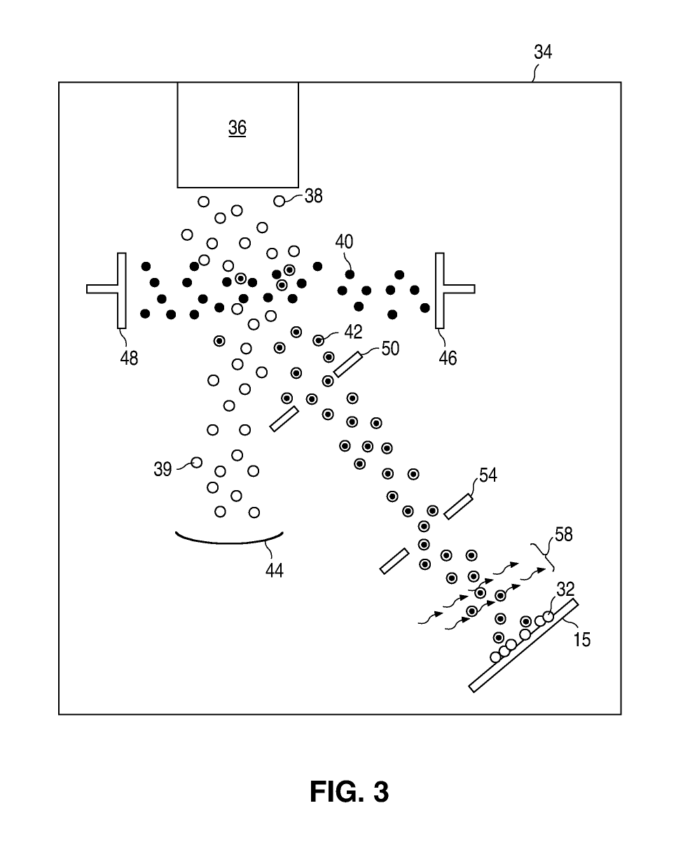

A phosphor layer 32 is formed on the surface of n-type region 12 by one of the methods described below in the text accompanying FIG. 3. The thickness of the phosphor layer is selected to wavelength convert all or part of the light emitted by active region 14 of LED 15. The thickness may depend on the particular phosphor and the concentration of wavelength converting dopant in the phosphor. Phosphor layer 32 is between 10 and 200 microns thick in some embodiments, between 10 and 50 microns thick in some embodiments, and between 10 and 30 microns thick in some embodiments. Multiple phosphors which emit different wavelengths of light may be included in phosphor layer 32. Multiple phosphors may be mixed in a single layer or formed as discrete layers. Phosphor layer 32 may be, for example, an inorganic powder phosphor such as Y₃Al₅O₁₂:Ce³⁺, referred to herein as YAG:Ce, which emits yellow light when pumped by light from a blue-emitting LED. Any other suitable phosphor may be used in addition to or instead of YAG:Ce in phosphor layer 32. Examples of suitable phosphors include (Sr,Ca,Mg,Ba,Zn)(Al,B,In,Ga)(Si,Ge)N₃:Eu²⁺, (Sr,Ca,Mg,Ba,Zn)(Al,B,In,Ga)(Si,Ge)N₃₋ₐOₐ:Eu²⁺ or Ce³⁺ 0≦a≦1, CaAlSiN₃:Eu²⁺, (Sr, Ca)AlSiN₃:Eu²⁺, (Lu,Y,Gd)₃(Al,Ga)₅O₁₂:Ce³⁺, Lu₃Al₅O₁₂:Ce³⁺, (Sr,Ba,Ca)Si₅₋ₐAlₐN₈₋ₐOₐ:Eu²⁺ 0≦a≦5, Sr₂Si₅N₈:Eu²⁺, (Sr,Ca,Ba)SiNO:Eu²⁺, SrSi₂N₂O₂:Eu²⁺, (Sr,Mg,Ca,Ba)(Ga,Al,In)S₄:Eu²⁺, SrGa₂S₄:Eu²⁺, SrBaSiO₄:Eu²⁺, (Ca,Sr)S:Eu²⁺, CaS:Eu²⁺, and SrS:Eu²⁺.

Phosphor layer 32 is formed by supplying enough energy to phosphor particles to cause the particles to adhere to the surface of LED 15, then bringing the particles in contact with LED 15. The phosphor particles may adhere to the surface without a subsequent anneal.

In some embodiments, enough heat is supplied to the phosphor particles to cause them to become molten. The particle size is selected such that the amount of heat required is insufficient to appreciably raise the temperature of the surface of LED 15. When the molten phosphor particles contact the surface of LED 15, they solidify. The process is repeated until the desired thickness of phosphor layer 32 is reached.

In some embodiments, kinetic rather than thermal energy is supplied to the phosphor particles. The phosphor particles are accelerated until they have a similar amount of kinetic energy as the thermal energy required to melt the particles. The surface of LED 15 is then bombarded with the high speed phosphor particles which adhere to the surface of LED 15. The particle size is selected such that the high speed phosphor particles do not damage the surface of LED 15.

In some embodiments, a combination of thermal and kinetic energy is used to cause the phosphor particles to adhere to the surface of LED 15.

FIG. 3 illustrates a method of forming phosphor layer 32. The process takes place in a reduced-pressure chamber 34. The pressure in chamber 34 may be less than atmospheric pressure and is substantially a vacuum in some embodiments.

Phosphor particles 38 are provided to chamber 34 by a phosphor dispersing assembly 36 which separates each phosphor particle from other phosphor particles. Particles 38 are then passed through a beam of electrons 40 generated between anode 46 and cathode 48. Electrons 40 charge phosphor particles 38. Unused phosphor particles 39 are collected by catch 44 and potentially returned to assembly 36.

The charged phosphor particles 42 are directed by an electric field generated between plates 50 and 54 toward the target surface, LED 15 in FIG. 3. In some embodiments, charged phosphor particles 42 are accelerated by the electric field between plates 50 and 54 such that they have sufficient kinetic energy to adhere to LED 15 on contact with the surface of LED 15, without being heated.

In some embodiments, charged phosphor particles 42 are passed through a beam 58 of infra-red radiation such that they become molten and solidify on contact with the target surface, LED 15 in FIG. 3. When the phosphor particles are heated to cause them to adhere to the target surface, techniques other than an electron beam and electric field, such as gravity, may be used to direct the phosphor particles to the target surface. In some embodiments, a microwave field, in addition to or instead of an infra-red beam, is used to heat the phosphor particles.

In some embodiments, charged phosphor particles 42 are accelerated by the electric field, then heated by infra-red beam 58, such that the combined kinetic and thermal energy of each particle when it contacts the target surface is enough to cause the particle to adhere to the target surface.

In one example, the phosphor is YAG:Ce, which melts at a temperature greater than 1200° C. The phosphor particles are between one and five microns in diameter. The particles are heated with an infra-red source at a wavelength that the YAG:Ce absorbs until they become molten. For example, a 1 kW-class standard industrial CO₂ laser with an intensity on the order of 1 kW/cm² to 100 kW/cm² may be used. The amount of time the phosphor particles are exposed to the beam may depend on the melting point of the phosphor, the size and speed of the phosphor particles, and the beam geometry. In some embodiments, the phosphor particles are exposed to the beam for milliseconds. When the molten droplets contact the surface of the LED, they solidify. The LED surface is bombarded with molten YAG:Ce droplets until a phosphor layer of the desired thickness is formed.

Alternatively, the YAG:Ce particles may be accelerated by the electric field to a speed of approximately 1 km/sec. At that speed, a particle that is three microns in diameter has about 50 mJ of kinetic energy, which is about the amount of energy required to melt the particle. The LED is bombarded with accelerated particles, which deform and adhere to the LED on contact, until a phosphor layer of the desired thickness is formed.

In some embodiments, other wavelength converting layers are combined with phosphor layer 32. For example, a second phosphor layer formed by the methods described in the text accompanying FIG. 3 may be formed over phosphor layer 32. Other wavelength converting materials may be formed or positioned over phosphor layer 32 or between phosphor layer 32 and LED 15, before or after phosphor layer 32, such as a pre-formed ceramic phosphor layer that is attached to LED 15 or phosphor layer 32 or a powder phosphor disposed in an organic encapsulant that is stenciled, screen printed, or dispensed over LED 15 or phosphor layer 32. In some embodiments, phosphor layer 32 is formed on a ceramic phosphor layer that is attached, for example by an adhesive such as silicone, to LED 15 before or after forming phosphor layer 32.

In some embodiments, phosphor layer 32 is encapsulated by a transparent material such as epoxy or silicone, for example to protect phosphor layer 32 or to form a lens or other optic. The transparent material may be formed after phosphor layer 32 is formed, such that the transparent material is not required to adhere phosphor layer 32 to LED 15.

In some embodiments, phosphor layer 32 is formed on a surface that is separate from the light emitting device. For example, phosphor layer 32 may be formed on a glass or other transparent plate which is spaced apart from the light source in a display. Alternatively, phosphor layer 32 may be formed on a ceramic phosphor that is spaced apart from the light emitting device.

The wavelength converting layers described in the embodiments may have several advantages. No organic binder is required, either to bind the phosphor together or to attach a ceramic phosphor to the LED, which may eliminate problems associated with the organic binder. The wavelength converting layer may be dense and thermally conductive, which may improve the performance of the device. The thickness of the wavelength converting layer may be tightly controlled, which may improve both the performance of the device and control of the characteristics of light emitted by the device and may reduce the cost of the device by eliminating waste of wavelength converting material. The wavelength converting layer may be fairly scattering, which may improve homogeneity of light emitted by the device without significant loss of light. Processes for forming the wavelength converting layer are generally inexpensive.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A method comprising:
supplying energy to a particle of wavelength converting material; and
causing the particle to contact a surface;
wherein the energy causes the particle to adhere to the surface on contact with the surface.

2. The method of claim 1 wherein supplying energy comprises heating.

3. The method of claim 2 wherein heating comprises heating until the particle becomes molten.

4. The method of claim 1 wherein supplying comprises exposing the particle to infrared radiation.

5. The method of claim 1 wherein supplying comprises exposing the particle to microwaves.

6. The method of claim 1 wherein supplying energy comprises accelerating.

7. The method of claim 1 wherein the surface is a surface of a semiconductor light emitting device.

8. The method of claim 1 wherein the surface is a transparent plate.

9. The method of claim 1 wherein the surface is a surface of a ceramic phosphor.

10. The method of claim 1 wherein the particle is phosphor.

11. The method of claim 1 wherein causing the particle to contact a surface comprises:
charging the particle with an electron beam; and
directing the charged particle toward the surface with an electric field.

12. A method comprising:
passing a stream of particles of phosphor through an electron beam to charge at least some of the particles in the stream;
directing the charged particles with an electric field toward a surface of a III-nitride light emitting device; and
supplying the charged particles with sufficient energy such that when the charged particles contact the surface of the light emitting device a portion of the charged particles adhere to the surface.

13. The method of claim 12 wherein supplying comprises exposing the charged particles to infrared radiation.

14. The method of claim 12 wherein supplying comprises exposing the charged particles to microwaves.

15. The method of claim 12 wherein supplying comprises accelerating the charged particles toward the surface with the electric field.
